(19) United States
(12) Patent Application Publication
(10) Pub. No.: US 2024/0334686 A1
(43) Pub. Date: Oct. 3, 2024

(54) SEMICONDUCTOR STRUCTURE AND METHOD FOR FORMING THE SAME

(71) Applicant: Winbond Electronics Corp., Taichung City (TW)

(72) Inventors: Cheng-Chiang LI, Taichung City (TW); Wei-Kuan YU, Changhua County (TW)

(21) Appl. No.: 18/621,622

(22) Filed: Mar. 29, 2024

(30) Foreign Application Priority Data
Mar. 31, 2023 (TW) 112112506

(51) Int. Cl. H10B 12/00; H01L 23/528

(52) U.S. Cl. CPC H10B 12/50; H01L 23/5283; H10B 12/482; H10B 12/485

(57) ABSTRACT

A semiconductor structure includes a central region and a periphery region. The periphery region surrounds the central region. The semiconductor structure includes a target layer pattern formed in the central region, and a dummy pattern formed in the periphery region, and the target layer pattern and the dummy pattern are formed by the target layer. The dummy pattern includes a first portion and a second portion. The extending direction of the second portion is different from the extending direction of each of the target layer patterns, and the first portion and the second portion extend in different directions. The second portion of one of the dummy patterns is connected to one of the target layer patterns or the first portion.

### CROSS REFERENCE TO RELATED APPLICATIONS

This Application claims priority of Taiwan Patent Application No. 112112506, filed on Mar. 31, 2023, the entirety of which is incorporated by reference herein.

### BACKGROUND OF THE INVENTION

### Field of the Invention

The present invention relates to semiconductor structures, and, in particular, to high-reliability dummy patterns.

### Description of the Related Art

As the dimensions of integrated circuits (ICs) are scaled down, the pattern in the array region is also scaled down, for example, the size of the active area is scaled down. If a dummy active area located in the periphery of an IC adopts the same pattern as the active area in the central region, it may generate flaws or defects due to the dummy active area being too small, or it may bend, displace, or collapse due to processing factors. This may cause electrical or structural defects. Moreover, the process window is relatively small. In addition, an existing solution to prevent the dummy active areas from collapsing is to connect all the dummy active areas. However, as the process continues to be scaled down, the connected dummy active areas may easily cause short circuits between adjacent bit lines located above. Therefore, there is a need to improve the design of dummy patterns, for example, dummy active areas to avoid defects and increase the process window.

### BRIEF SUMMARY OF THE INVENTION

The present invention provides a semiconductor structure to strengthen the periphery of the array region to avoid defects and thereby improve the yield.

An embodiment of the present invention provides a semiconductor structure having a central region and a periphery region surrounding the central region. The semiconductor structure comprises a plurality of target layer patterns and a plurality of dummy patterns. The target layer patterns are formed in the central region. The dummy patterns are formed in the periphery region. All of the target layer patterns and the dummy patterns are made from a target layer. The dummy patterns comprise a first portion and a second portion. The extending direction of the second portion is different from the extending direction of each of the target layer patterns, and the first portion and the second portion extend in different directions. The second portion of one of the dummy patterns is connected to one of the target layer patterns or the first portion.

In addition, an embodiment of the present invention provides a method of forming a semiconductor structure. The method comprises patterning a target layer to form a plurality of target layer strip structures in a central region of the semiconductor structure, cutting the target layer strip structures to form a plurality of target layer patterns, and cutting the target layer in a periphery region surrounding the central region to form a plurality of dummy patterns. The dummy patterns comprise a first portion and a second portion. The extending direction of the second portion is different from the extending direction of each of the target layer patterns, and the first portion and the second portion extend in different directions. The second portion of one of the dummy patterns is connected to one of the target layer patterns or the first portion.

An embodiment of the present invention provides a semiconductor structure and a method for forming the same. The dummy patterns (such as dummy active area) are formed in the periphery region and have different extending directions from the target layer patterns in the central region. Moreover, the dummy patterns have a greater width than the width of the target layer patterns, which may enhance the structure of the dummy patterns, avoid collapse, bending, or displacement, and avoid process defects and holes. In addition, the dummy patterns of the present invention may reduce environmental variations at the periphery of the central region and increase process window. In addition, the dummy patterns of the present invention may also avoid potential short-circuit, thereby improving the yield and benefiting the miniaturization of the semiconductor structure.

### BRIEF DESCRIPTION OF THE DRAWINGS

Aspects of the present disclosure are best understood from the following detailed description when read with the accompanying figures. It is noted that, various features are not drawn to scale. The dimensions of the various features may be arbitrarily increased or reduced for clarity of discussion.

FIGS. 1A-1F are cross-sectional views of various stages for forming a semiconductor structure, in accordance with some embodiments.

FIGS. 1A-1, 1D-1, 1E-1, 1F-1, and 1G are top views of various stages for forming a semiconductor structure, in accordance with some embodiments.

FIG. 2 is a top view of a semiconductor structure, in accordance with some embodiments.

FIG. 3 is a top view of a semiconductor structure, in accordance with some embodiments.

### DETAILED DESCRIPTION OF THE INVENTION

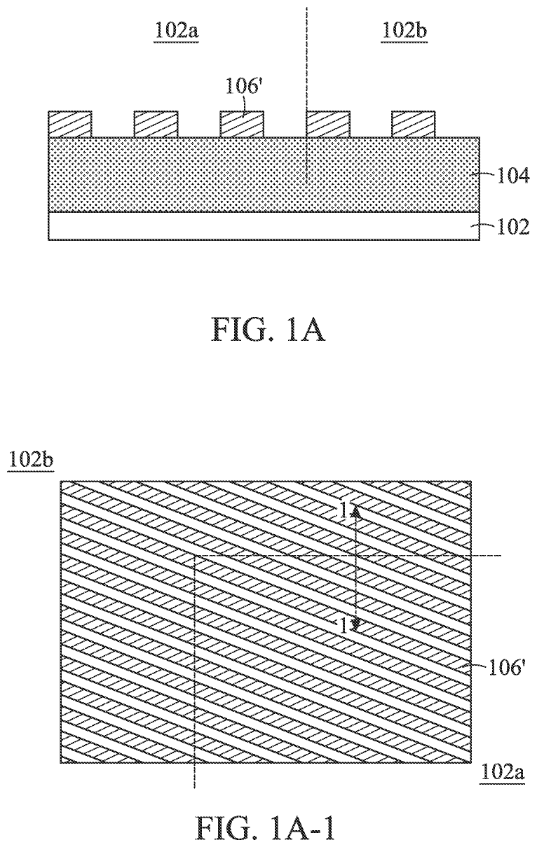

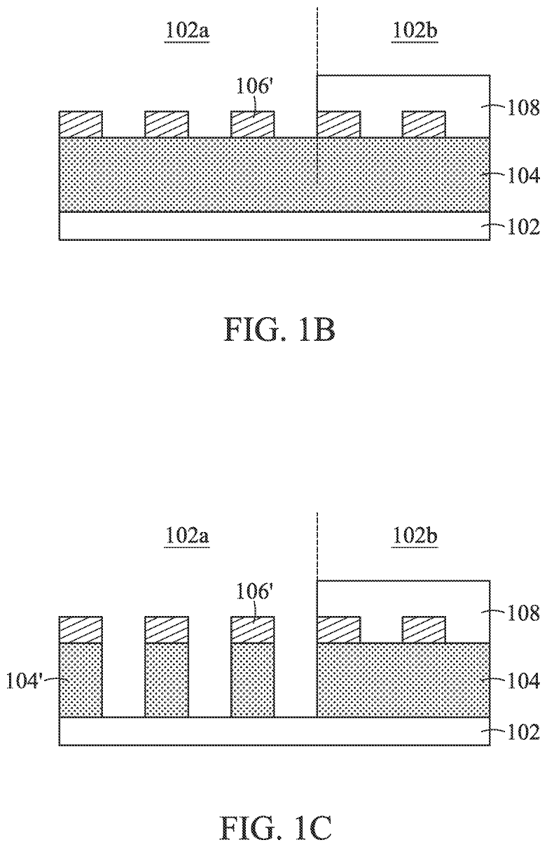

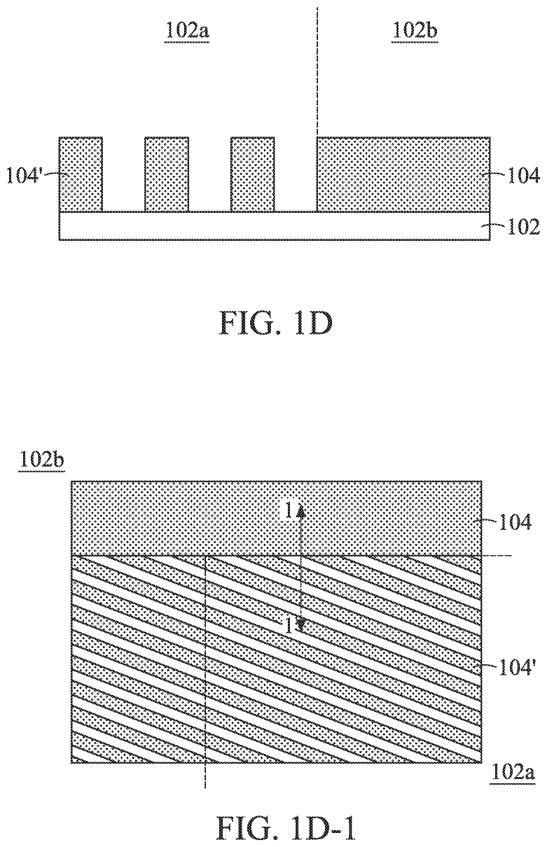

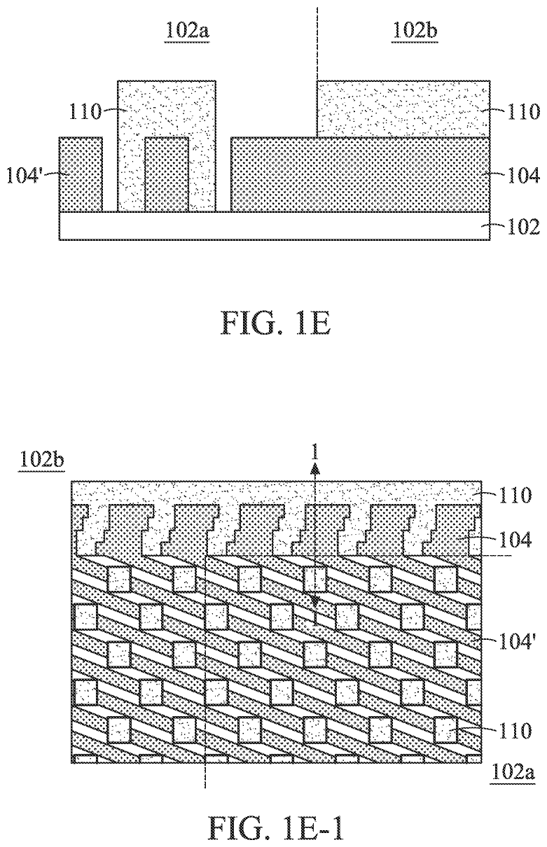

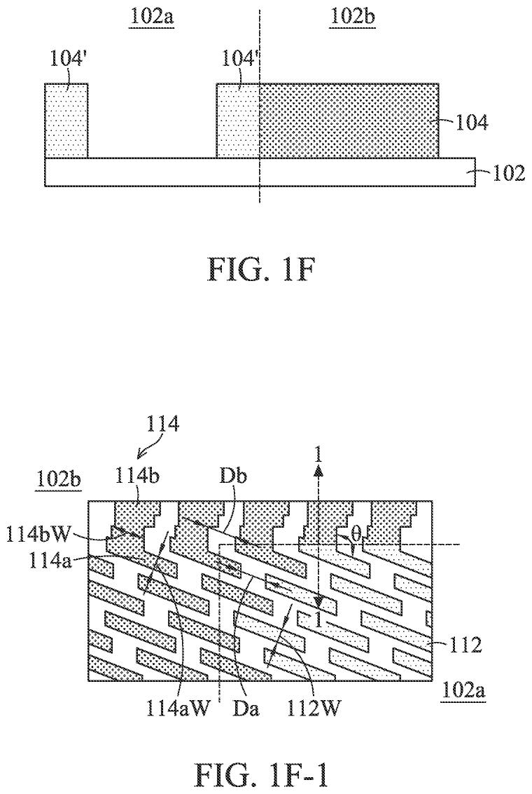

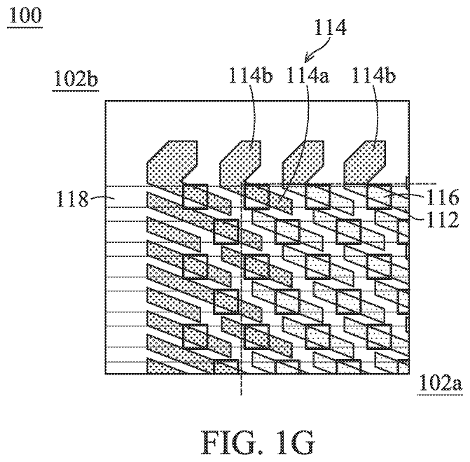

FIGS. 1A-1, 1D-1, 1E-1, 1F-1, and 1G are top views of various stages for forming a semiconductor structure 100, in accordance with some embodiments. FIGS. 1A, 1D, 1E, and 1F are cross-sectional views of the semiconductor structure 100 taken along line 1-1 in FIGS. 1A-1, 1D-1, 1E-1, and 1F-1, respectively.

The semiconductor structure 100 of this embodiment may include a memory semiconductor structure, such as a dynamic random access memory (DRAM), a flash memory, any semiconductor structures having a central region and a periphery region, or a combination thereof. As shown in FIGS. 1A and 1A-1, the semiconductor structure 100 includes a substrate 102, which includes a central region (also called as an array region) 102a and a periphery region 102b surrounding the central region 102a. The substrate 102 may be a semiconductor substrate, which may include an elementary semiconductor, such as silicon (Si), germanium (Ge), or the like; a compound semiconductor, such as gallium nitride (GaN), silicon carbide (SiC), gallium arsenide (GaAs), phosphorus Gallium (GaP), indium phosphide (InP), indium arsenide (InAs), indium antimonide (InSb), or the like; an alloy semiconductor such as silicon germanium alloy (SiGe), gallium arsenic phosphorus alloy (GaAsP), aluminum indium arsenide Alloy (AlInAs), arsenic aluminum gallium alloy (AlGaAs), arsenic indium gallium alloy (GaInAs), phosphorus indium gallium alloy (GaInP), phosphorus indium gallium arsenic alloy (GaInAsP), or a combination thereof. In addition, the substrate 102 may also be a silicon-on-insulator (SOI). The substrate 102 may include N-type or P-type conductivity type region. Dopants in the N-type region may include phosphorus (P), arsenic (As), antimony (Sb) ions, or a combination thereof. Dopants in the P-type region may include boron (B), gallium (Ga), aluminum (Al), indium (In), boron trifluoride ions (BF3⁺), or a combination thereof.

Next, a target layer 104 to be patterned is formed on the substrate 102. Alternatively, the substrate 102 may serve as the target layer 104 to be patterned. In this embodiment, the target layer 104 to be patterned may be the substrate 102, and a plurality of active areas or dummy active areas may be defined in the substrate 102 according to the present invention. In other embodiments (not shown), a semiconductor material layer, including silicon, is formed on the substrate 102 as the target layer 104 to be patterned, but the invention is not limited thereto. Next, a hard mask layer is formed on the target layer 104, and the hard mask layer is patterned to form a plurality of hard mask strips 106′ in the central region 102a and the periphery region 102b. In some embodiments, the hard mask layer includes a nitride, such as silicon nitride. The target layer 104 and the hard mask layer may be formed by a deposition process, such as a chemical vapor deposition (CVD) process, a spin coating process, a sputtering process, or a combination thereof. In some embodiments, the hard mask strips 106′ are equal in width and parallel to each other.

Next, a photoresist layer 108 is formed on the hard mask strip 106′ and the target layer 104 in the periphery region 102b, and the hard mask strip 106′ and the target layer 104 in the central region 102a are exposed, as shown in FIG. 1B. In this embodiment, the photoresist layer 108 is formed on the first side of the periphery region 102b (the area covered by the target layer 104 as shown in FIG. 1D-1), and the hard mask strips 106′ and the target layer 104 on the second side of the periphery region 102b are exposed, wherein the first side and the second side are perpendicular to each other.

Next, the photoresist layer 108 and the hard mask strips 106′ are used as masks to etch the target layer 104, thereby forming a plurality of target layer strip structures 104′ in the central region 102a, as shown in FIG. 1C. The target layer strip structures 104′ have the same width and parallel to each other, and each target layer strip structure 104′ extends in the same direction as the respective hard mask strips 106′. The target layer 104 may be removed by a wet etching process or a dry etching process.

Next, all of the photoresist layer 108 and the hard mask strips 106′ are removed, and the target layer strip structures 104′ in the central region 102a and the target layer 104 in the periphery region 102b are exposed, as shown in FIGS. 1D and 1D-1. The photoresist layer 108 may be removed by an ashing process, and the hard mask strips 106′ may be removed by a wet etching process, such as a process using phosphoric acid (H₃PO₄) as an etching solution. In this embodiment, the second side of the periphery region 102b also has target layer strip structures 104′ extending from the target layer strip structures 104′ in the central region 102a.

Next, a cutting pattern 110 covering the target layer strip structures 104′ in the central region 102a and the target layer 104 in the periphery region 102b is formed, as shown in FIGS. 1E and 1E-1. The cutting pattern 110 is configured to cut the target layer strip structures 104′ in the central region 102a and the target layer 104 in the periphery region 102b into a plurality of portions, respectively. In some embodiments, the cutting pattern 110 has a plurality of staggered rectangular patterns in the central region 102a, and each of the rectangular patterns covers the top surface and sidewalls of the desired cut-off portions of the target layer strip structures 104′, respectively. In other words, each width of the rectangular patterns of the cutting pattern 110 is greater than the width of the desired cut-off portions of the target layer strip structures 104′ in the central region 102a. The cutting pattern 110 has a comb-like pattern in the periphery region 102b.

Next, as shown in FIGS. IF and 1F-1 (only a part of FIG. 1E-1 is shown), the portion of the target layer 104 covered by the cutting pattern 110 is removed to form target layer patterns and dummy patterns, and the cutting pattern 110 is removed. In this embodiment, the target layer patterns are active areas 112, and the dummy patterns are the dummy active areas 114. In some embodiments, the dummy active areas 114 include L-shaped patterns, and each of the L-shaped patterns includes a first portion 114a and a second portion 114b. The first portion 114a of the L-shaped pattern extends in the same direction as the active area 112, while the second portion 114b of the L-shaped pattern extends in different directions from the first portion 114a. In some embodiments, the dummy active areas 114 further include stripe patterns, whose width and size are substantially equal to the active area 112. The area of the L-shaped pattern is greater than the area of the active area 112.

In some embodiments, the angle θ between the first portion 114a and the second portion 114b of the dummy active area 114 may not be less than 20 degrees and may be less than 180 degrees. In a preferred embodiment, the first portion 114a of the dummy active area 114 is perpendicular to the second portion 114b of the dummy active area 114, which can effectively reduce the influence of process stress.

By forming the dummy active area 114 with L-shaped patterns or L-shaped like patterns on at least one side of the central region 102a, the structure of the dummy active area 114 can be strengthened to avoid bending or displacement caused by stress during the manufacturing process and also to prevent the dummy patterns from collapsing due to being too small. In addition, environmental variations at the periphery of the central region 102a can be reduced, and the process window can be increased.

In some embodiments, the distance Da between the first portion 114a of the dummy active area 114 and the adjacent active area 112 is approximately equal to the distance Db between adjacent second portions 114b of the dummy active areas 114. This prevents the generation of voids during the manufacturing process, which would adversely affect the yield.

In some embodiments, the width of the first portion 114a of the dummy active area 114 is 114aW, the width of the second portion 114b of the dummy active area 114 is 114bW, and the width of the active area 112 is 112W. In some embodiments, the first portion 114a and the second portion 114b of the dummy active area 114 have different widths. In some embodiments, the width 114bW of the second portion 114b of the dummy active area 114 is greater than the width 114aW of the first portion 114a of the dummy active area 114. In some embodiments, the width 114aW of the first portion 114a of the dummy active area 114 is substantially equal to the width 112W of the active area 112. As a result, environmental variations around the central region 102a can be reduced, and the process window can be increased.

In some embodiments, by forming the second portions 114b of the dummy active areas 114 separated from each other, it is possible to avoid potential short-circuit and deterioration of the yield.

Next, contacts 116 are formed over the active areas 112 and the dummy active areas 114, and bit lines 118 are formed over the contacts 116, as shown in FIG. 1G. The contacts 116 are configured to electrically connect the active areas 112 and the dummy active areas 114 to the bit lines 118. In some embodiments, the contacts 116 are arranged in a staggered manner. The bit lines 118 have the same width and parallel to each other. The extending direction of the bit line 118 is different from the extending direction of the first portion 114a and the second portion 114b of the dummy active area 114. In the top view, the orthogonal projection of the second portion 114b of the dummy active area 114 does not overlap with the orthogonal projection of the bit line 118.

The contacts 116 may be formed by depositing conductive materials or semiconductor materials (such as polysilicon). The bit line 118 includes a barrier layer and a conductive layer. The materials of the barrier layer include titanium (Ti), titanium nitride (TiN), tantalum (Ta), tantalum nitride (TaN), tungsten nitride (WN), other suitable materials, or a combination thereof. The conductive layer includes metal materials (such as tungsten (W), aluminum (Al), or copper (Cu)), metal alloys, or a combination thereof. The barrier layer and conductive layer of the bit line 118 may be deposited using an atomic layer deposition (ALD) process.

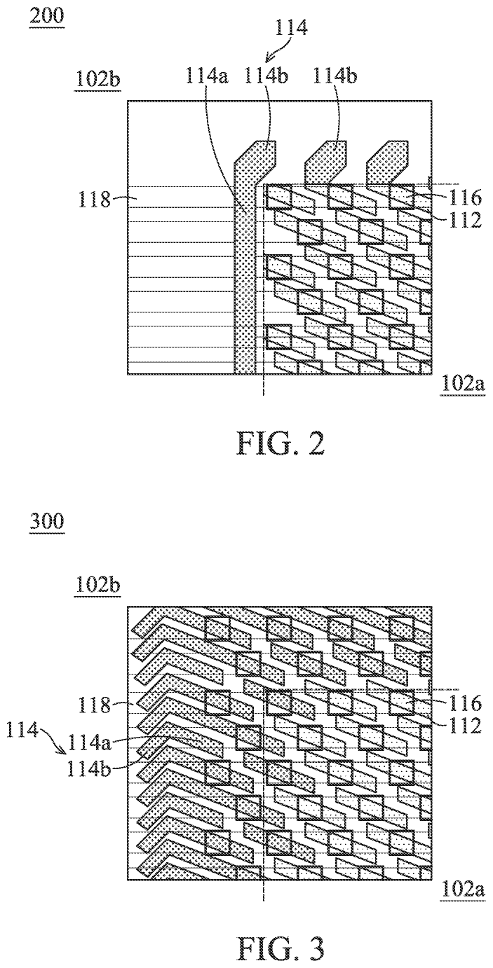

FIG. 2 is a top view of a semiconductor structure 200, in accordance with some embodiments. Processes or components that are the same or similar to those in the previous embodiments are designated the same reference numbers, and their details will not be repeated herein for brevity. The difference from the previous embodiment is that, on the second side of the periphery region 102b, the first portion 114a of the dummy active area 114 is configured as a strip pattern across a plurality of bit lines 118, as shown in FIG. 2. In particular, on the second side of the periphery region 102b, the extending direction of the first portion 114a of the dummy active area 114 is perpendicular to the extending direction of the bit line 118. As a result, the area of the dummy active areas 114 may be reduced, thereby reducing the area of the semiconductor structure 200.

In some embodiments, the contacts 116 are not disposed on the second side of the periphery region 102b. Furthermore, on the second side of the periphery region 102b, the first portion 114a of the dummy active area 114 is separated from the adjacent active area 112. Therefore, a short circuit between adjacent bit lines 118 may be avoided.

FIG. 3 is a top view of a semiconductor structure 300, in accordance with some embodiments. Processes or components that are the same or similar to those in the previous embodiments are designated the same reference numbers, and their details will not be repeated herein for brevity.

As shown in FIG. 3, the orthogonal projection of the first portion 114a and the second portion 114b of the dummy active area 114 partially overlap with the orthogonal projection of a corresponding bit line 118. On the first side of the periphery region 102b, the dummy active area 114 have a stripe pattern extending from the periphery region 102b to the central region 102a, and its width and size are substantially equal to the active area 112. On the second side of the periphery region 102b, the dummy active area 114 have L-shaped patterns with a first portion 114a and a second portion 114b extending from the periphery region 102b to the central region 102a. In addition, the second portions 114b of the adjacent L-shaped patterns are separated from each other, which may avoid potential short-circuit and deterioration of yield.

It should be noted that the position and direction of the L-shaped dummy active area 114 shown in the embodiment of the present invention are only illustrative, and the invention is not limited thereto. The L-shaped dummy active area 114 may be formed in any direction around the central region 102a and may extend in different directions, depending on the manufacturing process and design requirements.

In summary, an embodiment of the present invention forms the dummy patterns (such as the dummy active areas) with L-shaped patterns on at least one side of the central region, the area of the dummy pattern is larger than the area of the target layer pattern (such as the active area) located in the central region. It can protect the structure of the dummy patterns and avoid deformation of the dummy patterns during the manufacturing process, which will affect the adjacent target layer pattern located in the central region, thereby impacting the yield. In addition, an embodiment of the present invention can also reduce environmental variations at the periphery of the central region and increase the process window. In addition, the L-shaped dummy patterns can avoid potential short-circuit and may also reduce the area of the semiconductor memory structure, which is beneficial to miniaturization.

The present invention is suitable for making miniaturized semiconductor devices, so as to increase the total number of dies on a wafer. Therefore, the production cost and energy consumption of manufacturing a single IC are reduced, and the production energy consumption of subsequent packaging is also reduced, thereby reducing carbon emissions in the process of producing semiconductor devices. Besides, the present disclosure provides a green technology by improving the reliability and yield and benefiting the miniaturization of the semiconductor structure, thereby leading to more efficient use of resources and reduction of waste.

What is claimed is:

1. A semiconductor structure having a central region and a periphery region surrounding the central region, the semiconductor structure comprising:
a plurality of target layer patterns formed in the central region; and
a plurality of dummy patterns formed in the periphery region, and all of the target layer patterns and the dummy patterns made from a target layer,
wherein the dummy patterns comprise a first portion and a second portion,
wherein an extending direction of the second portion is different from an extending direction of each of the target layer patterns, and the first portion and the second portion extend in different directions,
wherein the second portion of one of the dummy patterns is connected to one of the target layer patterns or the first portion.

2. The semiconductor structure of claim 1, wherein the target layer is a substrate or a semiconductor material layer, and an area of each of the dummy patterns is greater than an area of each of the target layer patterns.

3. The semiconductor structure of claim 1, wherein a width of the second portion is greater than a width of each of the target layer patterns.

4. The semiconductor structure of claim 1, further comprising:
a bit line extending in different directions than each of the target layer patterns, wherein the first portion of one of the dummy patterns extends in a same direction as each of the target layer patterns.

5. The semiconductor structure of claim 1, wherein an angle between the first portion and the second portion of the dummy patterns is not less than 20 degrees and is less than 180 degrees.

6. The semiconductor structure of claim 1, wherein adjacent ones of the second portion of the dummy patterns are separated by a first distance, and the first portion of the dummy patterns are separated from an adjacent one of the target patterns by a second distance equal to the first distance.

7. The semiconductor structure of claim 1, further comprising:
a bit line extending in different directions than each of the target layer patterns,
wherein the second portion of one of the dummy patterns is connected to the first portion and is not connected to the target layer patterns, and an extending direction of the first portion is perpendicular to an extending direction of the bit line,
wherein the second portion of another one of the dummy patterns is connected to the target layer patterns.

8. The semiconductor structure of claim 7, further comprising:
a plurality of contacts formed on each of the target layer patterns to electrically connect the target layer patterns to the bit line,
wherein the contacts are not formed on the first portion.

9. The semiconductor structure of claim 4, wherein an orthogonal projection of the first portion and the second portion of one of the dummy patterns partially overlaps an orthogonal projection of the bit line.

10. The semiconductor structure of claim 1, wherein adjacent ones of the dummy patterns are separated from each other.

11. The semiconductor structure of claim 1, wherein an orthogonal projection of the second portion of the dummy patterns does not overlap an orthogonal projection of the bit line.

12. A method of forming a semiconductor structure, comprising:
patterning a target layer to form a plurality of target layer strip structures in a central region of the semiconductor structure;
cutting the target layer strip structures to form a plurality of target layer patterns; and
cutting the target layer in a periphery region surrounding the central region to form a plurality of dummy patterns,
wherein the dummy patterns comprise a first portion and a second portion, wherein an extending direction of the second portion is different from an extending direction of each of the target layer patterns, and the first portion and the second portion extend in different directions,
wherein the second portion of one of the dummy patterns is connected to one of the target layer patterns or the first portion.

13. The method of claim 12, wherein patterning the target layer comprises:
forming a hard mask layer on the target layer;
patterning the hard mask layer to form a plurality of hard mask strips;
forming a photoresist layer to cover the periphery region; and
etching the target layer to form the target layer strip structures in the central region by using the hard mask layer and the photoresist layer as a mask.

14. The method of claim 13, wherein cutting the target layer strip structures and the target layer comprises:
forming a cutting pattern partially covering the target layer and the target layer strip structures in the periphery region, wherein the cutting pattern has a plurality of staggered rectangular patterns in the central region, a width of each of the rectangular patterns is greater than a width of a desired cut-off portion of each of the target layer strip structures; and
removing a portion of the target layer covered by the cutting pattern.

15. The method of claim 12, wherein the first portion and the second portion of the dummy patterns have different widths.

16. The method of claim 12, wherein a width of the second portion of the dummy patterns is greater than a width of the first portion of the dummy patterns.

17. The method of claim 12, further comprising:
forming a plurality of contacts on each of the target layer patterns; and
forming a bit line on the contacts.

18. The method of claim 12, wherein the first portion of the dummy patterns is perpendicular to the second portion of the dummy patterns.

19. The method of claim 12, wherein adjacent ones of the second portion of the dummy patterns are separated from each other.

20. The method of claim 12, wherein a width of the second portion is greater than a width of each of the target layer patterns.
